(19) United States
(12) Patent Application Publication
(10) Pub. No.: US 2019/0127846 A1
(43) Pub. Date: May 2, 2019

(54) METHOD FOR PRODUCING AMORPHOUS CARBON COATINGS ON EXTERNAL SURFACES USING DIAMONDOID PRECURSORS

(71) Applicant: DURALAR TECHNOLOGIES, LLC, Tucson, AZ (US)

(72) Inventors: Andrew Tudhope, Tucson, AZ (US); Salvatore Gennaro, Trento (IT); Thomas B. Casserly, San Ramon, CA (US)

(21) Appl. No.: 15/794,951

(22) Filed: Oct. 26, 2017

(51) Int. Cl. C23C 16/26; C23C 16/455; C23C 16/505; C23C 16/46

(52) U.S. Cl. CPC C23C 16/26; C23C 16/46; C23C 16/505; C23C 16/45565

(57) ABSTRACT

The invention relates to a method for depositing high sp³ content amorphous carbon coatings onto external surfaces. This method allows adjustment of tribological properties, such as hardness, Young's modulus, wear resistance, and coefficient of friction as well as optical properties, such as refractive index. In addition, the resulting coatings are uniform and have high corrosion resistance. By controlling pressure, type of diamondoid precursor, and bias voltage, the method prevents the diamondoid precursor from fully breaking upon impact with the substrate. The diamondoid retains sp³ bonds which yields a high sp³ content film. This enables a faster deposition rate than would be possible without the use of a diamondoid precursor.

### FIELD OF THE INVENTION

The present invention relates to the deposition of carbon based coatings onto the surfaces of articles and relates particularly, but not exclusively, to the deposition of such coatings onto metallic surfaces such as, for example an external surface.

### BACKGROUND OF THE INVENTION

Prior art coating methods for formation of diamond-like carbon (“DLC”) include chemical vapor deposition (“CVD”), physical vapor deposition (“PVD”), and plasma enhanced chemical vapor deposition (“PECVD”) methods. Many of the desirable properties of DLC are determined by the amount of carbon that undergoes sp³ bonding (i.e., diamond) compared to the amount of carbon that undergoes sp² bonding (i.e., graphite). By increasing the sp³/sp² ratio, it is possible to achieve many of the excellent tribological properties of diamonds, such as high hardness, high Young's modulus, low wear, and low friction, as well as corrosion resistance.

Composite coatings based on DLC have also been shown to have desirable properties. For example, layered films using a material of low modulus followed by a material of high hardness (e.g., tungsten carbide/carbon) have been shown to have increased wear resistance. Similarly, a “nano-composite” can be used. A nano-composite is formed by mixing the materials instead of layering, so that the nano-sized crystals of a very hard material (e.g., TiN) are embedded in the amorphous DLC matrix. A nano-composite can also involve two or more different amorphous matrices, such as a C—H matrix and separate metal-metal matrix as described in U.S. Pat. No. 7,786,068 to Dorfman et al. In the prior art, high quality films were not produced solely by PECVD techniques, but rather by PVD techniques or a hybrid PVD/PECVD method.

The formation of prior art DLC films is fully described in “Diamond-Like amorphous carbon,” J. Robertson, Materials Science and Engineering R 37 (2002) pages 129-281; incorporated herein by reference. The commonly accepted model of DLC formation is commonly referred to as the subplantation model.

Prior art PECVD of DLC based coatings relies on ion bombardment energy to form sp³. Without this, graphite will form instead of diamond. It has been found that approximately 100 eV of energy on the C+ ion is needed to maximize the sp³ content. At very high ion energy, films with high sp² content are formed. At very low ion energy, the result from prior art techniques is high hydrogen content polymers. Carbon ion energy is a function of bias voltage, pressure, precursor gas, and plasma density. High plasma density, low pressure (<1e⁻³ Torr) PECVD techniques such as electron cyclotron resonance have generated the highest sp³ content PECVD films, with reports of up to 70% sp³ content. However, these processes are limited to low pressure so the deposition rate is very slow (˜1 micron/hr).

Higher pressure (>10 mTorr) PECVD techniques have the advantage of higher deposition rates, however current higher pressure techniques cannot produce high sp³ content films due to the lack of a collision-less plasma sheath. This means that the mean free path of the ion is less than that of the plasma sheath width, resulting in low ion energy. Additionally, the ratio of (free) radicals to ions is higher at high pressure which results in sp² rich films. A high level of radicals vs. ions is detrimental to DLC properties, as radicals are highly reactive but lack the energy of ions. To form high quality DLC it is important to have a large portion of film deposition due to ion flux vs. non-ionized (or radical) flux, due to the importance of ion bombardment energy. Since the ion/radical ratio decreases with increasing pressure, prior art processes for sp³ formation were limited to low pressure, and the resulting low deposition rates that go along with low pressure.

There is a trend in increasing hardness with increasing saturation, or sp³ bonding, of the precursor molecule. This is because molecules such as acetylene with two pi bonds are more likely to form reactive radicals than a molecule such as methane with sp³ bonding or no pi bonds. Thus, a higher hardness film is produced by methane then acetylene, conversely due to the higher radical reactivity the acetylene based coating will have a higher deposition rate than the methane based coating.

Most prior art precursors are hydrocarbons such as methane, acetylene and benzene. The precursor used to form the film will change the carbon energy due to the breakup of the molecule on impact with the surface. Thus, a carbon atom produced from acetylene (C₂H₂) will have approximately one-half the energy of a carbon atom from methane (CH₄). Therefore, a high bias voltage is normally required to produce high sp³ content films when larger precursor molecules are used. The use of a large hydrocarbon precursor can also have negative effects, such as a large thermal spike.

Prior art PECVD techniques contained substantial amounts of hydrogen due to the hydrogen contained in the hydrocarbon precursor which is incorporated into the DLC. This hydrogen has detrimental effects such as lowering the hardness and temperature stability of the coating.

Compared to CVD techniques, PECVD allows coating at lower temperature because the energy is supplied by the plasma rather than heat. This is important in the instance where the substrate is temperature-sensitive.

Plasma immersion ion implantation and deposition (“PIID”) techniques have been shown to be useful for coating the external surfaces of complex shapes. PIID is performed by applying a negative bias to a workpiece, this bias will pull positive ions toward the workpiece if the plasma sheath is conformal. There are also improvements that can be made to film properties such as adhesion and film density via ion bombardment of the workpiece.

Use has been made of high sp³ seed material in prior art PECVD formation of carbon-coated O₂ barrier films on plastic materials. For example, EP 0763 144 B1 uses a diamondoid precursor at very low concentration (<10%) compared to the concentration of a standard hydrocarbon precursor such as acetylene. In the prior art, however, the ability to control film properties is limited by both the low concentration of diamondoid and the inability to control ion bombardment energy.

Diamondoids of the adamantane series are hydrocarbons composed of fused cyclohexane rings that form interlocking cage structures that are very stable. The lower diamondoids have chemical formulas of C₄ₙ₊₆H₄ₙ₊₁₂ where n is equal to the number of cage structures. A complete description of these materials can be found in “Isolation and Structure of Higher Diamondoids, Nanometer-Sized Diamond Molecules” (Dahl, Liu & Carlson, Science, January 2003, Vol. 299); incorporated herein by reference. The first three unsubstituted diamondoids are adamantane, diamantane and triamantane.

The term “diamondoids” refers to substituted and unsubstituted caged compounds of the adamantane series including adamantane, diamantane, triamantane, tetramantane, pentamantane, hexamantane, heptamantane, octamantane, nonamantane, decamantane, undecamantane, and the like, including all isomers and stereoisomers thereof. The compounds have a “diamondoid topology,” which means their carbon atom arrangement is superimposable on a fragment of an FCC diamond lattice. Substituted diamondoids comprise from 1 to 10, and preferably 1 to 4, independently-selected alkyl substituents. Diamondoids include “lower diamondoids” and “higher diamondoids”, as well as mixtures of any combination of lower and higher diamondoids.

The term “lower diamondoids” refers to adamantane, diamantane, triamantane, and any and/or all unsubstituted and substituted derivatives of adamantane, diamantane, and triamantane. These unsubstituted lower diamondoid components show no isomers or chirality and are readily synthesized, distinguishing them from “higher diamondoids.”

The term “higher diamondoids” refers to any and/or all substituted and unsubstituted tetramantane components; to any and/or all substituted and unsubstituted pentamantane components; to any and/or all substituted and unsubstituted hexamantane components; to any and/or all substituted and unsubstituted heptamantane components; to any and/or all substituted and unsubstituted octamantane components; to any and/or all substituted and unsubstituted nonamantane components; to any and/or all substituted and unsubstituted decamantane components; to any and/or all substituted and unsubstituted undecamantane components; as well as mixtures of the above and isomers and stereoisomers of tetramantane, pentamantane, hexamantane, heptamantane, octamantane, nonamantane, decamantane, and undecamantane.

Adamantane chemistry has been reviewed by Fort et al. in “Adamantane: Consequences of the Diamondoid Structure,” Chem. Rev. vol. 64, pp. 277-300 (1964). Adamantane is the smallest member of the diamondoid series and may be thought of as a single cage crystalline subunit. Diamantane contains two subunits, triamantane three, tetramantane four, and so on. While there is only one isomeric form of adamantane, diamantane, and triamantane, there are four different isomers of tetramantane (two of which represent an enantiomeric pair), i.e., four different possible ways of arranging the four adamantane subunits. The number of possible isomers increases non-linearly with each higher member of the diamondoid series, (e.g., pentamantane, hexamantane, heptamantane, octamantane, nonamantane, decamantane, etc.).

Adamantane, which is commercially available, has been studied extensively. The studies have been directed toward a number of areas, such as thermodynamic stability, functionalization, and the properties of adamantane-containing materials. For instance, the following patents discuss materials comprising adamantane subunits: U.S. Pat. No. 3,457,318 teaches the preparation of polymers from alkenyl adamantanes; U.S. Pat. No. 3,832,332 teaches a polyamide polymer forms from alkyladamantane diamine; U.S. Pat. No. 5,017,734 discusses the formation of thermally stable resins from adamantane derivatives; and U.S. Pat. No. 6,235,851 reports the synthesis and polymerization of a variety of adamantane derivatives. The use of lower diamondoid moieties in conventional polymers is known to impart superior thermal stability and mechanical properties.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### SUMMARY OF THE INVENTION

The present invention features a system for enabling a deposition of a diamond-like carbon (“DLC”) coating onto an external surface of a substrate disposed within a deposition chamber having an initial pressure at atmospheric level and an operating pressure between about 0.1 mTorr and 20 mTorr. In some embodiments, the system comprises: a roughing valve, having a roughing valve first end and a roughing valve second end; a soft start valve, having a soft start valve first end and a soft start valve second end; and a backing valve, having a backing valve first end and a backing valve second end. In one embodiment, the roughing valve first end is operatively coupled to the deposition chamber. In another embodiment, the soft start valve first end is operatively coupled to both the roughing valve first end and to the deposition chamber. In a further embodiment, the backing valve second end is also operatively coupled to the soft start valve second end.

In additional embodiments, the system further comprises: a plurality of turbomolecular pumps, each having a first end and a second end; a plurality of pendulum isolation valves, each having an isolation valve first end and an isolation valve second end; and a vacuum pump operatively coupled to the backing valve second end. In some embodiments, the first end of each turbomolecular pump is operatively coupled to the backing valve first end. In other embodiments, each isolation valve first end is operatively coupled to the deposition chamber, while each isolation valve second end is operatively coupled to the second end of a turbomolecular pump.

In supplementary embodiments, the soft start valve and the roughing valve operate to evacuate pressure within the deposition chamber, such that the initial pressure drops from atmospheric pressure to a sub-atmospheric level. Pressure may be further evacuated from the deposition chamber via the plurality of turbomolecular pumps to establish the operating pressure of the deposition chamber. In some embodiments, the plurality of pendulum isolation valves isolate the plurality of turbomolecular pumps from the deposition chamber when the deposition chamber is at or near atmospheric pressure. In preferred embodiments, the backing valve mechanically pumps exhaust, generated by the plurality of turbomolecular pumps, via the vacuum pump. Consistent with previous embodiments, the pressure within the deposition chamber is established for facilitating the deposition of the DLC coating onto the external surface of the substrate.

In exemplary embodiments, a plasma beam source is established in a region adjacent the substrate by introducing a diamondoid precursor into the region and ionizing the diamondoid precursor via a first power supply. Following, a negative bias may be applied to the substrate via a second power supply. Ionization of the diamondoid precursor results in a formation of a plasma, which diffuses to the substrate from the region adjacent the substrate. Selection of the pressure and the negative bias results in the deposition of the DLC coating onto the external surface of the substrate.

In additional embodiments, the first power supply is a radio frequency (“RF”) generator and the second power supply is a DC pulsed power supply. An RF matching network may be coupled to the first power supply to compensate for the impedance of the plasma, thus effectively maximizing the power absorbed by the plasma.

The present invention further features a method for enabling a deposition of a DLC onto an external surface of a substrate disposed within a deposition chamber operating at a pressure between about 0.1 mTorr and 20 mTorr. In exemplary embodiments, the deposition chamber comprises a main chamber and a plasma source housing, which is a recessed portion of the deposition chamber adjacent the main chamber. In an embodiment, no physical barriers separate the plasma source housing from the main chamber. In another embodiment, the substrate to be coated is disposed in the main chamber.

In some embodiments, the method comprises the steps of: dropping the pressure within the deposition chamber from atmospheric pressure to a sub-atmospheric level via a soft start valve and a roughing valve; evacuating additional pressure from the deposition chamber via a plurality of turbomolecular pumps to establish the operating pressure; and mechanically pumping exhaust generated by the plurality of turbomolecular pumps via a backing valve operatively coupled to a vacuum pump. In an embodiment, the deposition chamber is isolated from the plurality of turbomolecular pumps via a plurality of pendulum isolation valves when the pressure is at or near atmospheric pressure.

In other embodiments the method further comprises: meting out a liquid diamondoid precursor via a liquid flow controller and a carrier gas via a dedicated mass flow controller to an evaporator mixer; heating the liquid diamondoid precursor and the carrier gas, via the evaporator mixer, to produce a precursor solution; and delivering the precursor solution to a deposition chamber via a heated delivery manifold. In additional embodiments, a plasma beam source is then created in the plasma source housing by:

introducing the precursor solution into the plasma source housing from the heated manifold via a plurality of symmetrically placed shower heads disposed along a height of the plasma source housing; and

generating a plasma by ionizing the precursor solution via a first power supply.

Following, a negative bias is applied to the substrate via a second power supply to stimulate diffusion of the plasma from the plasma source housing to the substrate, as a result of the attraction between the negatively biased substrate and positive ions of the plasma. In supplementary embodiments, the negative bias applied to the substrate causes bombardment of the ionized plasma molecules onto the external surface of the substrate, leading to a deposition of the diamond-like carbon coating onto the external surface of the substrate.

In the present system, the combination of the diamondoid precursor flow, control of a bias voltage, turbomolecular pumping with mechanical backing, and use of an RF plasma beam source provide for the generating of reactive species (from which to grow the DLC coating) at low pressure regimes. As previously mentioned, current PECVD technology employing high pressure (>10 mTorr) techniques cannot produce high sp³ content coatings. This limitation inhibits their ability to produce coatings having the aforementioned desirable tribological properties of diamonds (as an increase in the sp³/sp² ratio is required to achieve these properties). Moreover, current processes (i.e., PECVD) for producing high sp³ content coatings are limited to low pressure (<1 mTorr) and the resulting low deposition rates (˜1 micron/hr) that typically accompany low pressure regimes. In contrast, the low pressure regime (>0.1 mTorr) of the present system is not hindered by the use of PVD or small molecules PECVD (e.g., methane or acetylene). Instead, the present system uses molecular diamond precursors that are made up of sp³ hybridized carbon. This results in a higher sp³ content coating without considerably lowering deposition rates. Further, lowering the pressure regime, as performed by the present system, allows for a larger process window (e.g., operating pressures from about 0.1 mTorr to about 20 mTorr) through which to vary/optimize coating properties of the DLC coating.

The deposition of DLC coatings is described in Massler (U.S. Pat. No. 6,740,393). This coating description includes an adhesion layer, gradient layer, and DLC top coating. One of the advantages taught by Massler is a high deposition rate process preferably in the range from 1-4 microns/hour at a pressure from 10⁻³ to 10⁻² mbar (0.75-7.5 mTorr), the maximum hardness given in the examples taught by Massler is 2,500 HK. In comparison, the present invention achieves a higher deposition rate (about 1.5-7 microns/hour) with a tunable hardness of up to 2500 HV.

### BRIEF DESCRIPTION OF THE DRAWINGS

The features and advantages of the present invention will become apparent from a consideration of the following detailed description presented in connection with the accompanying drawings in which:

FIGS. 1A-1B show a flowchart of an embodiment of the method of the present invention.

FIG. 2 shows an embodiment of the system of the present invention.

FIG. 3 shows an embodiment of the plasma source housing.

FIG. 4 shows an alternate representation of the present system.

FIG. 5 shows a second alternate representation of the present system.

### DEFINITIONS

As used herein, the term “roughing valve” is defined as a valve isolating the vacuum pumping system from a deposition chamber to allow the chamber to be evacuated around, rather than through, the turbomolecular pumps.

As used herein, the term “soft start valve” is defined as a valve used to slowly evacuate a deposition chamber in order to prevent agitation of particulates that may otherwise be disturbed by the shock of a rapid pump down.

As used herein, the term “backing valve” is defined as a valve for isolating the exhaust of the turbomolecular pumps and the foreline of the vacuum pump. The backing valve also functions to allow/disallow the residual gases (evacuated from the main chamber by the turbomolecular pumps) to be pumped away from the exhaust line by the vacuum pump.

As used herein, the term “pendulum isolation valve” is defined as the isolation and pumping speed control between the deposition chamber and the inlet to the turbomolecular pumps.

As used herein, the term “turbomolecular pump” is defined as a turbine bladed high frequency rotational pump operating in a low pressure to molecular flow regime used to obtain and maintain low pressure in the deposition chamber.

### DETAILED DESCRIPTION OF THE INVENTION

Following is a list of elements corresponding to a particular element referred to herein:

201 liquid flow controller

202 substrate

203 dedicated mass flow controller

205 evaporator mixer

207 heated delivery manifold

209 deposition chamber

211 plasma source housing

212 main chamber

213 symmetrically placed shower heads

215 first power supply

217 second power supply

301 roughing valve

303 soft start valve

305 backing valve

307 turbomolecular pumps

309 pendulum isolation valves

311 vacuum pump

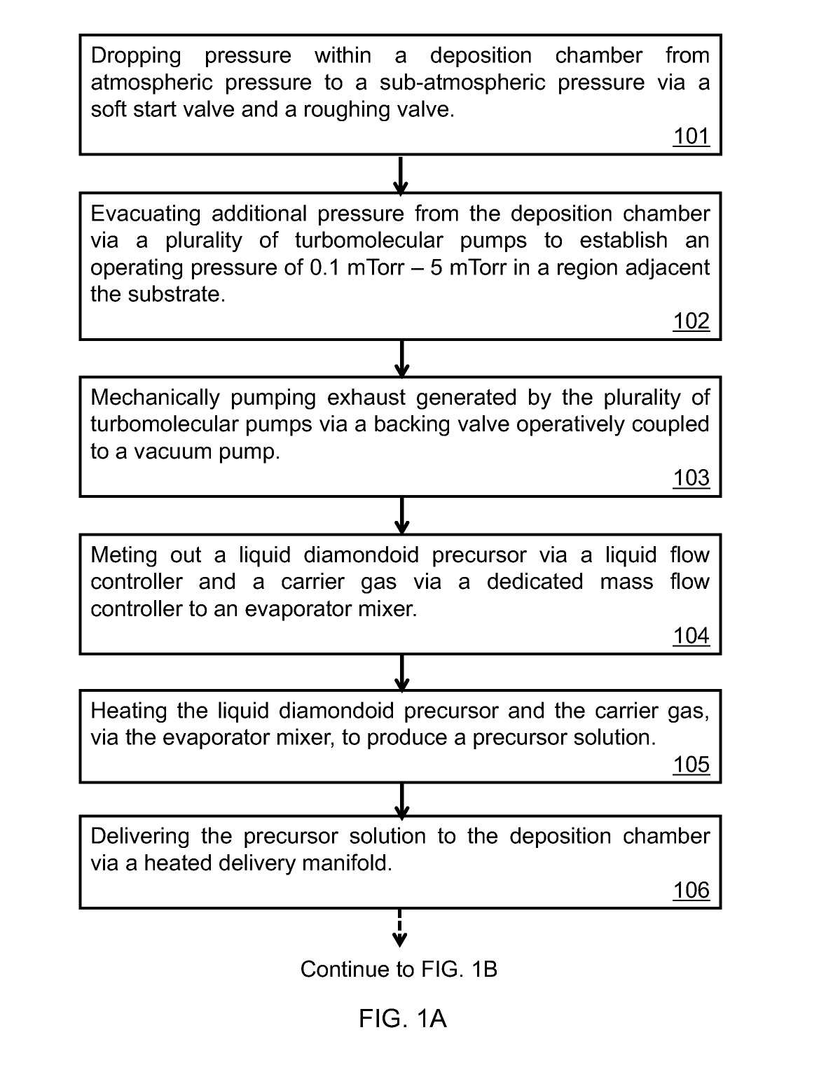

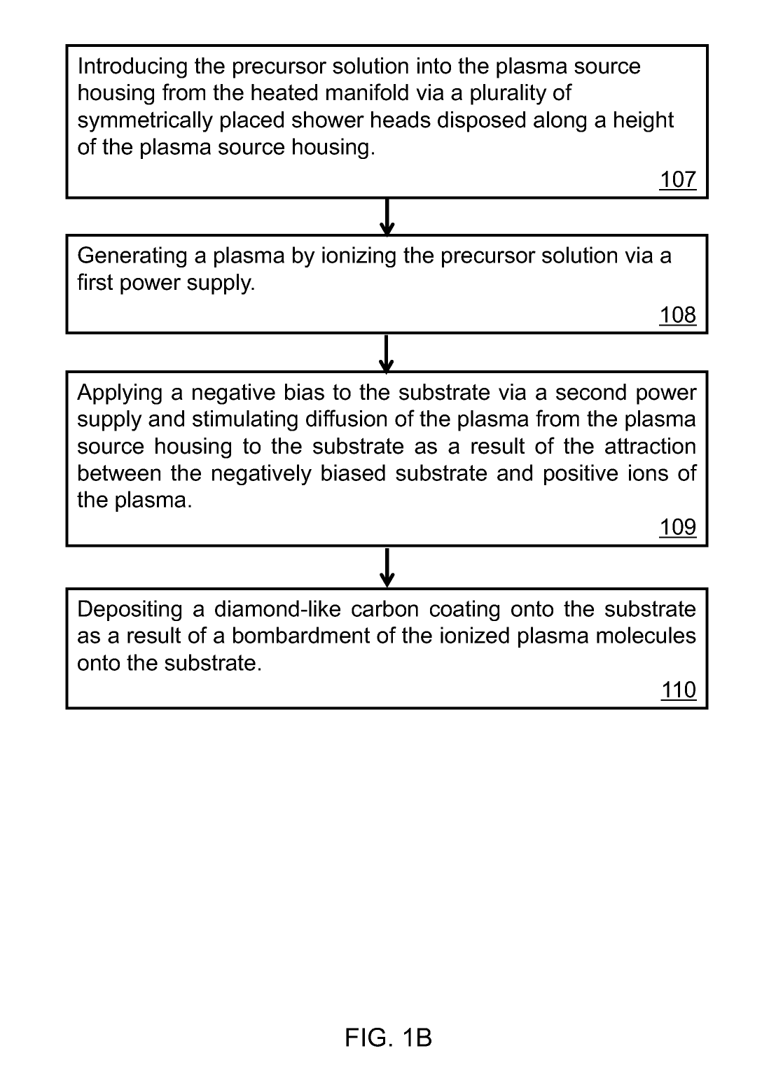

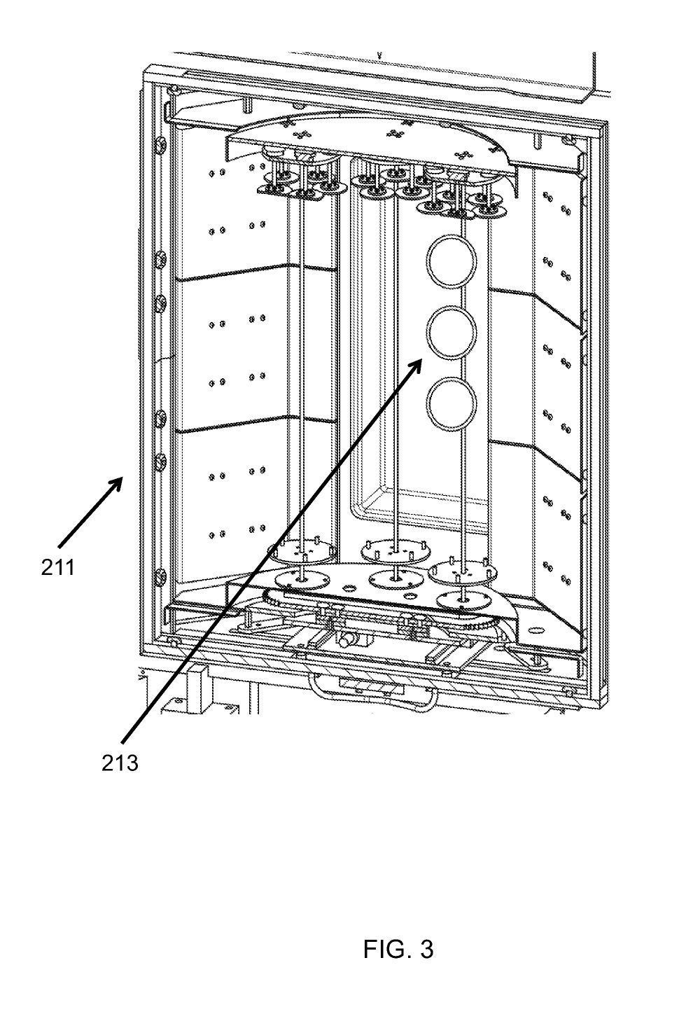

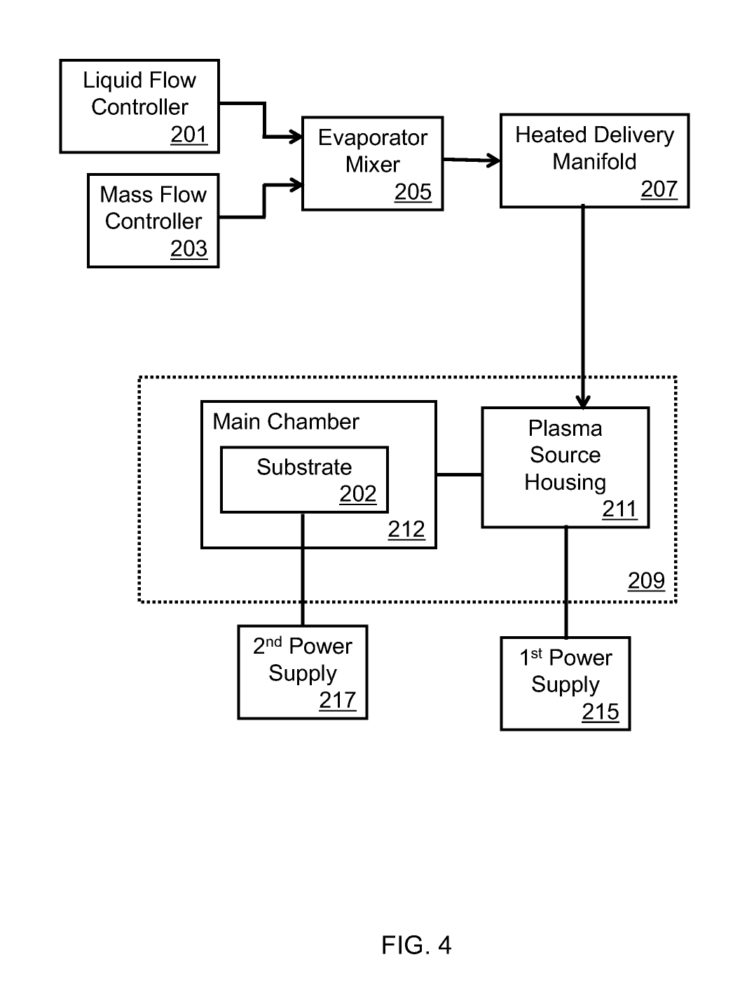

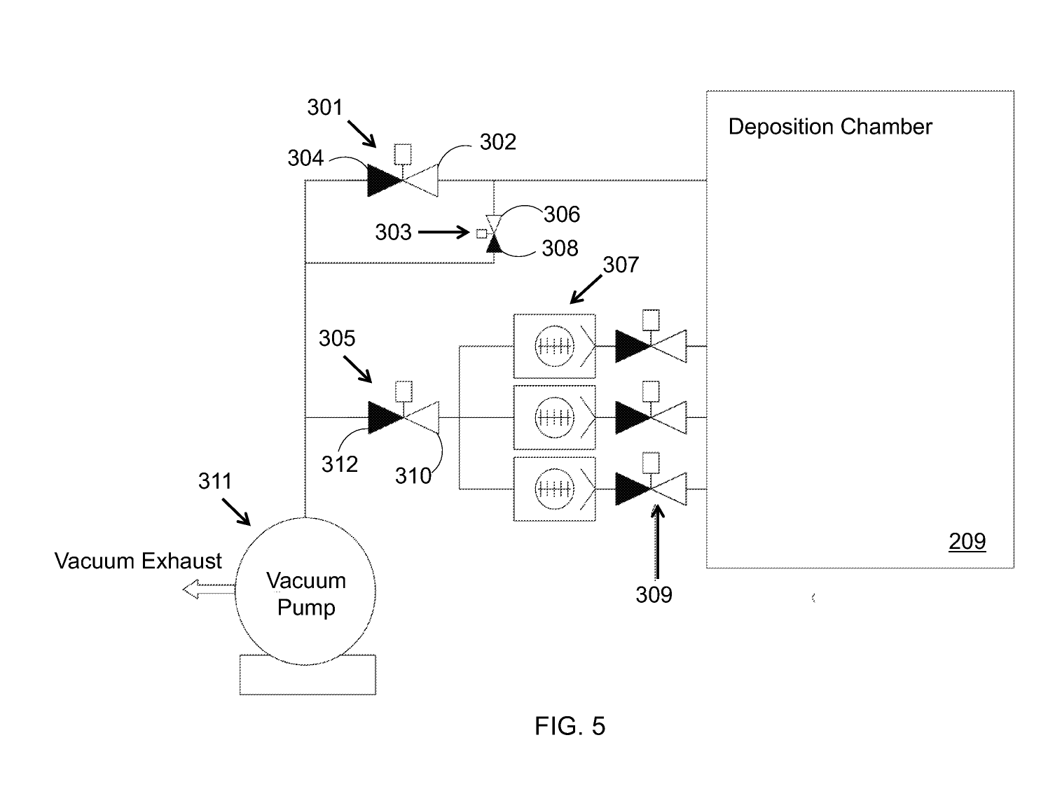

Referring now to FIGS. 1A-5, the present invention features a system for enabling a deposition of a DLC coating onto an external surface of a substrate (202) disposed within a deposition chamber having an initial pressure at atmospheric level and an operating pressure between about 0.1 mTorr and 20 mTorr. In some embodiments, the system comprises: a roughing valve (301), having a roughing valve first end (302) and a roughing valve second end (304); a soft start valve, (303) having a soft start valve first end (306) and a soft start valve second end (308); and a backing valve (305), having a backing valve first end (310) and a backing valve second end (312). In one embodiment, the roughing valve first end (302) is operatively coupled to the deposition chamber (209). In another embodiment, the soft start valve first end (306) is operatively coupled to both the roughing valve first end (302) and to the deposition chamber (209). In a further embodiment, the backing valve second end (312) is also operatively coupled to the soft start valve second end (308).

In additional embodiments, the system further comprises: a plurality of turbomolecular pumps (307), each having a first end and a second end; a plurality of pendulum isolation valves (309), each having an isolation valve first end and an isolation valve second end; and a vacuum pump (311) operatively coupled to the backing valve second end (312), the soft start valve second end (308), and the roughing valve second end (304). In an embodiment, the vacuum pump (311) is a mechanical pump. In some embodiments, the first end of each turbomolecular pump is operatively coupled to the backing valve first end (310). In other embodiments, each isolation valve first end is operatively coupled to the deposition chamber (209), while each isolation valve second end is operatively coupled to the second end of a turbomolecular pump.

In supplementary embodiments, driven by the vacuum pump (311), the soft start valve (303) and the roughing valve (301) operate to evacuate pressure within the deposition chamber (209), such that the initial pressure drops from atmospheric pressure to a sub-atmospheric level. Pressure may be further evacuated from the deposition chamber (209) via the plurality of turbomolecular pumps (307), driven by the vacuum pump (311), to establish the operating pressure of the deposition chamber (209). In some embodiments, the plurality of pendulum isolation valves (309) isolate the plurality of turbomolecular pumps (307) from the deposition chamber (209) when the deposition chamber (209) is at or near atmospheric pressure. In preferred embodiments, the backing valve (305) mechanically pumps exhaust, generated by the plurality of turbomolecular pumps (307), via the vacuum pump (311). Consistent with previous embodiments, the operating pressure within the deposition chamber (209) is established for facilitating the deposition of the DLC coating onto the external surface of the substrate (202).

In exemplary embodiments, a plasma beam source is established in a region adjacent the substrate (202) by introducing a diamondoid precursor into the region and ionizing the diamondoid precursor via a first power supply (215). Following, a negative bias may be applied to the substrate (202) via a second power supply (217). Ionization of the diamondoid precursor results in a formation of a plasma, which diffuses to the substrate (202) from the region adjacent the substrate (202). Selection of the pressure and the negative bias results in the deposition of the diamond-like carbon coating onto the external surface of the substrate (202).

In additional embodiments, the first power supply (215) is an RF generator and the second power supply (217) is a DC pulsed power supply. An RF matching network may be coupled to the first power supply (215) to compensate for the impedance of the plasma, thus effectively maximizing the power absorbed by the plasma.

In one embodiment, the diamondoid precursor is 1,3 dimethyl-adamantane. In an alternate embodiment, the diamondoid precursor is selected from a group consisting of an adamantane, a diamantane, a triamantane, or combinations thereof. In a further embodiment, the adamantane is present in an amount ranging from about 1% to 99% in said combinations. In supplementary embodiments, the diamondoid precursor is branched with a functional group, where the functional group is either organic or inorganic.

In some embodiments, the diamondoid precursor is introduced with an organic molecule, which may be in the form of an alkane, an alkene, an alkyne, or an aromatic compound, each having an organic chain of up to 12 carbon atoms. In other embodiments, deposition of the DLC coating onto the external surface of the substrate is performed by layering the diamondoid precursor with one or more reactive gases to form a composite coating.

The present invention further features a method for enabling a deposition of a DLC onto an external surface of a substrate disposed within a deposition chamber operating at a pressure between about 0.1 mTorr and 20 mTorr. In exemplary embodiments, the deposition chamber comprises a main chamber and a plasma source housing, which is a recessed portion of the deposition chamber adjacent the main chamber. In an embodiment, no physical barriers separate the plasma source housing from the main chamber. In another embodiment, the substrate to be coated is disposed in the main chamber.

In some embodiments the method comprises dropping the pressure within the deposition chamber from atmospheric pressure to a sub-atmospheric level via a soft start valve and a roughing valve (101); evacuating additional pressure from the deposition chamber via a plurality of turbomolecular pumps to establish the operating pressure (102); and mechanically pumping exhaust generated by the plurality of turbomolecular pumps via a backing valve operatively coupled to a vacuum pump (103). In an embodiment, the deposition chamber is isolated from the plurality of turbomolecular pumps via a plurality of pendulum isolation valves when the pressure is at or near atmospheric pressure.

In other embodiments the method further comprises the steps of: meting out a liquid diamondoid precursor via a liquid flow controller and a carrier gas via a dedicated mass flow controller to an evaporator mixer (104); heating the liquid diamondoid precursor and the carrier gas, via the evaporator mixer, to produce a precursor solution (105); and delivering the precursor solution to a deposition chamber via a heated delivery manifold (106). In additional embodiments, a plasma beam source is then created in the plasma source housing by:

introducing the precursor solution into the plasma source housing from the heated manifold via a plurality of symmetrically placed shower heads disposed along a height of the plasma source housing (107); and

generating a plasma by ionizing the precursor solution via a first power supply (108).

Following, a negative bias is applied to the substrate via a second power supply to stimulate diffusion of the plasma from the plasma source housing to the substrate, as a result of the attraction between the negatively biased substrate and positive ions of the plasma (109). In supplementary embodiments, the negative bias applied to the substrate causes bombardment of the ionized plasma molecules onto the external surface of the substrate, leading to a deposition of the diamond-like carbon coating onto the external surface of the substrate (110).

In some embodiments, an RF generator is employed as the first power supply and a DC pulsed power supply as the second power supply. An RF matching network may also be coupled to the first power supply to compensate for the impedance of the plasma, thus effectively maximizing the power absorbed by the plasma.

In one embodiment, the diamondoid precursor is 1,3 dimethyl-adamantane. In an another embodiment, the diamondoid precursor is selected from a group consisting of an adamantane, a diamantane, a triamantane, or combinations thereof. In further embodiments, the adamantane is present in an amount ranging from about 1% to 99% in said combinations.

In supplementary embodiments, the diamondoid precursor is branched with a functional group, where the functional group is either organic or inorganic.

In some embodiments, the diamondoid precursor is introduced with an organic molecule, which may be in the form of an alkane, an alkene, an alkine, or an aromatic compound, each having an organic chain of up to 12 carbon atoms.

In other embodiments, deposition onto the external surface of the substrate is performed by layering the diamondoid precursor with one or more reactive gases to form a composite coating.

A Non-Limiting Example

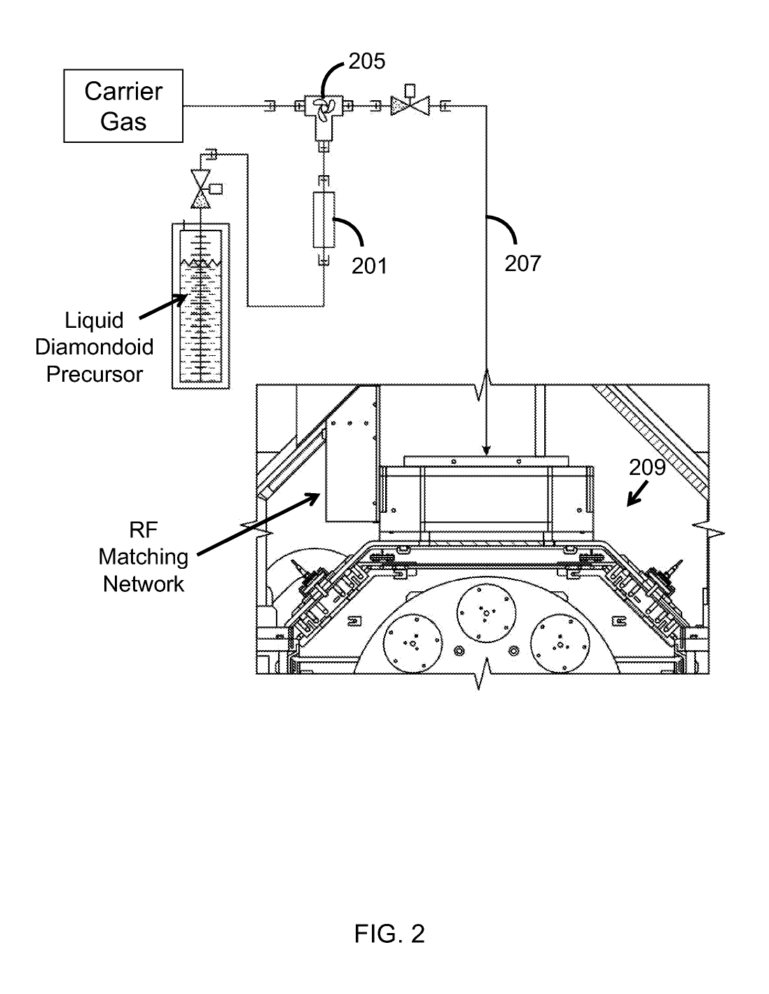

Without wishing to limit the invention to any theory or mechanism, FIGS. 2-4 present a non-limiting example of the system of the present invention. In some embodiments, the system (200) comprises: a liquid flow controller (201); a dedicated mass flow controller (203), an evaporator mixer (205) operatively coupled to the liquid flow controller (201) and the dedicated mass flow controller (203). In supplementary embodiments, the liquid flow controller (201) metes out a liquid diamondoid precursor to the evaporator mixer (205) and the dedicated mass flow controller (203) metes out the carrier gas to the evaporator mixer (205). The evaporator mixer (205) may then heat the liquid diamondoid precursor and the carrier gas to produce a precursor solution. In further embodiments, a heated delivery manifold (207) is operatively coupled to the evaporator mixer (205), for heating the precursor solution and delivering the precursor solution to a deposition chamber (209).

In additional embodiments, the deposition chamber (209) comprises a main chamber (212) and a plasma source housing (211). In an embodiment, a pressure level of the deposition chamber may be within the vacuum pressure range. In a further embodiment, the plasma source housing (211) is a recessed portion of the deposition chamber adjacent to the main chamber (212), where no physical barriers separate the plasma source housing (211) from the main chamber (212). In another embodiment, the substrate (202) to be coated is disposed in the main chamber (212). The plasma source housing (211) may also comprise a plurality of symmetrically placed shower heads (213) disposed along its height.

In supplementary embodiments, the system (200) further comprises a first power supply (215) operatively coupled to the plasma source housing (211) and a second power supply (217) applying a negative bias to the substrate (202).

Consistent with previous embodiments, a plasma beam source is created in the plasma source housing (211) by introducing the precursor solution into the plasma source housing (211) from the heated manifold (207) via the plurality of symmetrically placed shower heads (213) and ionizing the precursor solution via the first power supply (215) to generate a plasma. An attraction between the negative bias of the substrate (202) and positive ions of the plasma may then stimulate diffusion of the plasma from the plasma source housing (211) to the substrate (202). The negative bias of the substrate (202) further causes bombardment of the ionized plasma molecules onto the substrate (202). This bombardment results in the deposition of the diamond-like carbon coating onto the external surface of the substrate (202).

Further, the present system may simultaneously coat the external surface of a plurality of substrates of various geometries. Some non-limiting examples include about four (or more) 300 mm diameter silicon wafers or about three (or more) 500 mm diameter ceramic disks. Alternatively, hundreds to thousands of smaller components like automotive valve tappets, ball joints, gearing, armament trigger components and the like can be racked and coated simultaneously. Similarly, tens of thousands of screw heads or logos can be mounted to plates and coated simultaneously. Moreover, the present system has been demonstrated to allow the processing of up to eight single substrates, each having a cylindrical symmetry with a length of 100 cm and a diameter of 25 cm, with a total surface area of over 8,000 cm². Similarly, the system can coat stacks of piston rings (for example 81 mm diameter) on 16 to 20 mandrels coating 6000+ rings at a time. Still another non-limiting example is the coating of a thin single substrate having a height of up to about 1 meter and a length of up to about 2.8 meters.

As used herein, the term “about” refers to plus or minus 10% of the referenced number.

Various modifications of the invention, in addition to those described herein, will be apparent to those skilled in the art from the foregoing description. Such modifications are also intended to fall within the scope of the appended claims. Each reference cited in the present application is incorporated herein by reference in its entirety.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. Reference numbers recited in the claims are exemplary and for ease of review by the patent office only, and are not limiting in any way. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting of”, and as such the written description requirement for claiming one or more embodiments of the present invention using the phrase “consisting of” is met.

The reference numbers recited in the below claims are solely for ease of examination of this patent application, and are exemplary, and are not intended in any way to limit the scope of the claims to the particular features having the corresponding reference numbers in the drawings.

### REFERENCES

[1] “Diamond-Like amorphous carbon,” J. Robertson, Materials Science and Engineering R 37 (2002) pages 129-281.

[2] “Isolation and Structure of Higher Diamondoids, Nanometer-Sized Diamond Molecules,” Dahl, Liu & Carlson, Science, January 2003, Vol. 299.

What is claimed is:

1. A system for establishing an operating pressure within a deposition chamber to enable a deposition of a diamond-like carbon (“DLC”) coating onto an external surface of a substrate (202) disposed within the deposition chamber, wherein an initial pressure of the deposition chamber is at an atmospheric level and the operating pressure is between about 0.1 mTorr and 20 mTorr, the system comprising:
(a) a roughing valve (301) having a roughing valve first end (302) and a roughing valve second end (304), wherein the roughing valve first end (302) is operatively coupled to the deposition chamber (209);
(b) a soft start valve (303) having a soft start valve first end (306) and a soft start valve second end (308), wherein the soft start valve first end (306) is operatively coupled to the roughing valve first end (302) and to the deposition chamber (209);
(c) a backing valve (305) having a backing valve first end (310) and a backing valve second end (312), wherein the backing valve second end (312) is operatively coupled to the soft start valve second end (308);
(d) a plurality of turbomolecular pumps (307) each having a first end and a second end, wherein the first end of each turbomolecular pump is operatively coupled to the backing valve first end (310);
(e) a plurality of pendulum isolation valves (309) each having an isolation valve first end and an isolation valve second end, wherein each isolation valve second end is operatively coupled to the second end of a turbomolecular pump, wherein each isolation valve first end is operatively coupled to the deposition chamber (209); and
(f) a vacuum pump (311) operatively coupled to the backing valve second end (312), the soft start valve second end (308), and the roughing valve second end (304),
wherein, driven by the vacuum pump (311), the soft start valve (303) and the roughing valve (301) operate to evacuate pressure within the deposition chamber (209), such that the initial pressure drops from atmospheric level to a sub-atmospheric level, wherein pressure is further evacuated from the deposition chamber (209) via the plurality of turbomolecular pumps (307), driven by the vacuum pump (311), to establish the operating pressure within the deposition chamber (209), wherein the plurality of pendulum isolation valves (309) isolate the plurality of turbomolecular pumps (307) from the deposition chamber (209) when the deposition chamber (209) is at or near atmospheric pressure, wherein the backing valve (305) mechanically pumps exhaust generated by the plurality of turbomolecular pumps (307) via the vacuum pump (311),
wherein the operating pressure within the deposition chamber (209) is established for facilitating the deposition of the DLC coating onto the external surface of the substrate (202).

2. The system of claim 1, wherein a plasma beam source is established in a region adjacent the substrate (202) by introducing a diamondoid precursor into the region and ionizing the diamondoid precursor via a first power supply (215).

3. The system of claim 2, wherein a negative bias is applied to the substrate (202) via a second power supply (217), wherein ionization of the diamondoid precursor results in a formation of a plasma, wherein the plasma diffuses to the substrate (202) from the region adjacent the substrate (202), wherein selection of the pressure and the negative bias results in deposition of the diamond-like carbon coating onto the external surface of the substrate (202).

4. The system of claim 3, wherein the first power supply (215) is a radio frequency (“RF”) generator and the second power supply (217) is a DC pulsed power supply.

5. The system of claim 4, wherein an RF matching network, coupled to the first power supply (215), compensates for an impedance of the plasma to effectively maximize power absorbed by the plasma.

6. The system of claim 2, wherein the diamondoid precursor is an adamantane, a diamantane, a triamantane, or combinations thereof.

7. The system of claim 6, wherein the adamantane is present in an amount ranging from about 1% to 99% in said combinations.

8. The system of claim 2, wherein the diamondoid precursor is branched with a functional group, wherein the functional group is organic or inorganic.

9. The system of claim 2, wherein the diamondoid precursor is 1,3 dimethyl-adamantane.

10. The system of claim 2, wherein the diamondoid precursor is introduced with an organic molecule.

11. The system of claim 10, wherein the organic molecule is an alkane, an alkene, an alkyne, or an aromatic compound, each having an organic chain of up to 12 carbon atoms.

12. The system of claim 2, wherein deposition onto the substrate (202) is performed by layering the diamondoid precursor with one or more reactive gases to form a composite coating.

13. A method depositing a diamond-like carbon (“DLC”) coating onto an external surface of a substrate (202) disposed within a deposition chamber, wherein an initial pressure of the deposition chamber is at an atmospheric level and an operating pressure is between about 0.1 mTorr and 20 mTorr, wherein the deposition chamber comprises a main chamber and a plasma source housing, wherein the plasma source housing is a recessed portion of the deposition chamber adjacent the main chamber, wherein no physical barriers separate the plasma source housing from the main chamber, wherein the substrate to be coated is disposed in the main chamber, the method comprising:
(a) evacuating pressure from the deposition chamber, such that the pressure drops from atmospheric pressure to a sub-atmospheric level, via a soft start valve and a roughing valve (101);
(b) evacuating additional pressure from the deposition chamber via a plurality of turbomolecular pumps to establish the operating pressure of about 0.1 mTorr-5 mTorr in a region adjacent the substrate (102);
(c) mechanically pumping exhaust generated by the plurality of turbomolecular pumps via a backing valve operatively coupled to a vacuum pump (103);
(d) meting out a liquid diamondoid precursor via a liquid flow controller and a carrier gas via a dedicated mass flow controller to an evaporator mixer (104);
(e) heating the liquid diamondoid precursor and the carrier gas, via the evaporator mixer, to produce a precursor solution (105);
(f) delivering the precursor solution to the deposition chamber via a heated delivery manifold (106),
(g) creating a plasma beam source in the plasma source housing, the steps comprising:
(i) introducing the precursor solution into the plasma source housing from the heated manifold via a plurality of symmetrically placed shower heads disposed along a height of the plasma source housing (107), and
(ii) generating a plasma by ionizing the precursor solution via a first power supply (108); and
(h) applying a negative bias to the substrate via a second power supply, wherein an attraction between said negatively biased substrate and positive ions of the plasma stimulate diffusion of the plasma from the plasma source housing to the substrate (109),
wherein the negative bias applied to the substrate causes ion bombardment, via the ionized molecules in the plasma, leading to the deposition of the DLC coating onto the external surface of the substrate (110).

14. The method of claim 13, wherein the first power supply is a radio frequency (“RF”) generator and the second power supply is a DC pulsed power supply.

15. The method of claim 14, wherein an RF matching network, coupled to the first power supply, compensates for an impedance of the plasma to effectively maximize power absorbed by the plasma.

16. The method of claim 13, wherein the diamondoid precursor is an adamantane, a diamantane, a triamantane, or combinations thereof.

17. The method of claim 16, wherein the adamantane is present in an amount ranging from about 1% to 99% in said combinations.

18. The method of claim 13, wherein the diamondoid precursor is branched with a functional group, wherein the functional group is organic or inorganic.

19. The method of claim 13, wherein the diamondoid precursor is 1,3 dimethyl-adamantane.

20. The method of claim 13, wherein the diamondoid precursor is introduced into the deposition chamber with an organic molecule.

21. The method of claim 20, wherein the organic molecule is in the form of an alkane, an alkene, an alkyne, or an aromatic compound, each having an organic chain of up to 12 carbon atoms.

22. The method of claim 13, wherein deposition onto the substrate is performed by layering the diamondoid precursor with one or more reactive gases to form a composite coating.

23. The method of claim 13, wherein the deposition chamber is isolated from the plurality of turbomolecular pumps via a plurality of pendulum isolation valves when the pressure is at or near atmospheric pressure.
